(19) United States
(12) Patent Application Publication
(10) Pub. No.: US 2006/0186897 A1
(43) Pub. Date: Aug. 24, 2006

(54) Method and device for detecting two parameters of a fluid

(76) Inventor: Markus Niemann, Beckingen (DE)

Correspondence Address: KENYON & KENYON LLP, ONE BROADWAY, NEW YORK, NY, 10004, US

(21) Appl. No.: 11/353,417

(22) Filed: Feb. 13, 2006

(30) Foreign Application Priority Data
Feb. 18, 2005 (DE) 10 2005 007 544.4

(51) Int. Cl. G01R 27/04; G01R 27/32

(52) U.S. Cl. 324/633

(57) ABSTRACT

An oscillator is excited by a primary oscillator, and the excited oscillator is immersed in a fluid having two parameters, the first parameter of the fluid damping the excited oscillator via a first phase delay, and the second parameter damping the excited oscillator via a second phase delay. The oscillation of the excited and damped oscillator is detected as the oscillation signal. The oscillation signal is mixed with a phase-shifted signal generated from the excitation signal via a third phase delay which corresponds to either the first or the second phase delay. The mixed signal is averaged over time to determine the first or the second parameter according to the selection of the phase delay.

### CROSS-REFERENCE TO RELATED APPLICATIONS

The present application claims priority to Application No. 10 2005 007 544.4, filed in the Federal Republic of Germany on Feb. 18, 2005, which is expressly incorporated herein in its entirety by reference thereto.

### FIELD OF THE INVENTION

The present invention relates to a method and a device for detecting two parameters of a fluid. In particular, the present invention relates to the detection of the parameters via a sensor apparatus having an excited oscillator.

### BACKGROUND INFORMATION

The detection of physical properties and assigned variables (parameters) of a fluid, such as viscosity and permittivity, makes it possible to draw conclusions as to the chemical reactions in progress and the course thereof as well as to determine physical properties such as the mixing ratio of two fluids. Due to the lack of space in many reaction chambers and supply channels, only a limited number of sensors may be used. Sensors and devices for evaluating the sensors which support universal application and provide for the detection of a wide range of physical parameters are therefore believed to be needed.

Although example embodiments of the present invention may be applicable to any sensor apparatus having an excited oscillator for detecting two parameters of a fluid, an underlying problem is explained with regard to a viscosity and permittivity determination of a fluid, using an electrical oscillating circuit.

German Published Patent Application No. 199 58 769 describes a method and a device for evaluating a sensor apparatus which determines the viscosity of a fluid using an excited quartz immersed in the fluid. An oscillatory excitation signal is applied to the quartz. The resulting excitation amplitude is mixed in phase with the excitation signal and averaged over time to subsequently determine the active power of the immersed quartz. Because the active power rises as the viscosity of the fluid increases, it is possible to detect the viscosity.

According to conventional methods, the permittivity of a fluid may be detected via a coaxial structure which is immersed in the fluid. The application of an AC voltage potential makes it possible to determine the capacitance of the coaxial structure and thus the permittivity of the fluid.

A disadvantage may be that two sensors may be required to determine the permittivity and viscosity of a fluid.

### SUMMARY

An example embodiment of the present invention may provide a method which may provide for different signals to be detected using a single sensor apparatus.

The method according to an example embodiment of the present invention may provide that a single sensor apparatus may be used to detect two parameters of a fluid.

A first property of a fluid (e.g., liquid, gas or a mixture of the two) may result in damping of an excited oscillator via a first characteristic phase delay, and a second property may result in damping via a second characteristic phase delay. The two parameters of the fluid are determined individually by phase-locked detection of the oscillation of the excited oscillator to an exciting primary oscillator.

An oscillator having a primary oscillator is excited while the oscillator is in contact with the fluid, and the oscillator is excited by two parameters, the first parameter of the fluid damping the excited oscillator via a first phase delay and the second parameter damping the exciting oscillator via a second phase delay. The oscillation of the excited and damped oscillator is detected as the oscillation signal. The oscillation signal is mixed with a phase-shifted signal generated from the excitation signal via a third phase delay which corresponds to either the first or the second phase delay. The mixed signal is averaged over time to determine the first or the second parameter according to the selection of the third phase delay.

The following additional steps may be carried out sequentially or in parallel to the detection, mixing and averaging over time of the first signals: generation of a second phase-shifted signal via a fourth phase delay from the excitation signal, the fourth phase delay being the second phase delay from the first or second phase delay which was not selected; mixing of the oscillation signal with the second phase-shifted signal to generate a second mixed signal; and averaging over time of the second mixed signal to determine the other parameter of the fluid according to the fourth phase delay.

The third phase delay may be equal to 90° degrees and/or the fourth phase delay may be equal to 0°. The detection of the oscillation signal in phase determines the active power of the oscillator in the fluid, which is a measure, for example, of the viscosity of the fluid. For 90°, only the reactive power of the oscillator is determined by the first mixed signal. In the case of an electrical oscillating circuit, the capacitance, for example, may thus be determined for the permittivity of the fluid.

The oscillator may be an oscillating circuit, and the oscillation signal of the oscillating circuit may be detected as a current flowing from a ground to the oscillating circuit via a sensor resistor.

The excitation signal may be modulated by a central frequency using a modulation signal, a control signal may be generated by mixing the amplitude of the first or second mixed signal with the modulation signal, and the control signal may be supplied to the primary oscillator apparatus, thereby regulating the central frequency in resonance with a resonant frequency of the oscillating circuit.

An oscillator may be connected to a primary oscillator for the purpose of transmitting an excitation signal of the primary oscillator to the oscillator. A detecting apparatus may be connected to the sensor apparatus for the purpose of detecting the oscillation signal of the oscillating circuit. A first delay unit may be arranged between a mixer apparatus and the primary oscillator to generate a third phase-shifted signal and to supply it to the first mixer apparatus, which is connected to the sensor apparatus, and the first mixed signal is transmitted to a first filter apparatus for the purpose of averaging the first mixed signal over time.

The oscillating circuit may include a quartz.

The first delay unit may include an device having an adjustable phase delay.

A second mixer apparatus may be connected to the detecting apparatus and the primary oscillator for the purpose of mixing the oscillation signal with the excitation signal to generate a second mixed signal.

According to an example embodiment of the present invention, a method for detecting a first and a second parameter of a fluid with a sensor apparatus including an oscillator includes: exciting the oscillator by an excitation signal of a primary oscillator; exciting the oscillator via two parameters while the oscillator is in contact with the fluid, the first parameter of the fluid damping the excited oscillator via a first phase delay, and the second parameter damping the excited oscillator via a second phase delay; detecting an oscillation signal of the excited and damped oscillator; generating a first phase-shifted signal via a third phase delay from the excitation signal, the third phase delay equal to one of (a) the first phase delay and (b) the second phase delay; mixing the oscillation signal with the first phase-shifted signal to generate a first mixed signal; and averaging over time the first mixed signal to determine one of (a) the first parameter and (b) the second parameter of the fluid according to the third phase delay.

The method may include, one of (a) sequentially and (b) in parallel to the detection, mixing and averaging over time of the first signals: generating a second phase-shifted signal via a fourth phase delay from the excitation signal, the fourth phase delay being the second phase delay from one of (a) the first phase delay and (b) the second phase delay which was not selected; mixing the oscillation signal with the second phase-shifted signal to generate a second mixed signal; and averaging over time the second mixed signal to determine the other parameter of the fluid according to the fourth phase delay.

The oscillator may include an oscillation circuit, a current, which flows from a ground to the oscillation circuit via a sensor resistor, determined for detecting the oscillation signal of the excited oscillating circuit.

A third phase-shifted signal may be generated so that it is phase-shifted 90° in relation to the excitation signal, and/or a fourth phase-shifted signal may be generated so that it is phase-shifted 0° in relation thereto.

The method may include: modulating the excitation signal by a central frequency; obtaining a control signal by mixing one of (a) the first mixed signal and (b) the second mixed signal with the modulation signal; and supplying the control signal to the primary oscillator apparatus to regulate the central frequency in resonance with a resonant frequency of the oscillator

The oscillator may be excited in the exciting step in a resonant manner.

According to an example embodiment of the present invention, a device includes: an oscillator connected to a primary oscillator to transmit an excitation signal of the primary oscillator to the oscillator; a detection apparatus connected to sensor apparatus to detect an oscillation signal of an oscillating circuit; a first delay unit arranged between a mixer apparatus and the primary oscillator to generate a third phase-shifted signal and supply the third phase-shifted signal to the mixer apparatus, which is connected to the sensor apparatus and is adapted to transmit first mixed signal to a first filter apparatus to average the first mixed signal over time.

The device may be adapted to perform a method for detecting a first and a second parameter of a fluid with the sensor apparatus, the method including: exciting the oscillator by the excitation signal of the primary oscillator; exciting the oscillator via two parameters while the oscillator is in contact with the fluid, the first parameter of the fluid damping the excited oscillator via a first phase delay, and the second parameter damping the excited oscillator via a second phase delay; detecting the oscillation signal of the excited and damped oscillator; generating the first phase-shifted signal via a third phase delay from the excitation signal, the third phase delay equal to one of (a) the first phase delay and (b) the second phase delay; mixing the oscillation signal with the first phase-shifted signal to generate the first mixed signal; and averaging over time the first mixed signal to determine one of (a) the first parameter and (b) the second parameter of the fluid according to the third phase delay.

The oscillator may include a quartz.

The first delay unit includes a device having a settable phase delay.

The device may include a second mixer apparatus connected to the detection apparatus and the primary oscillator to mix the oscillation signal with the excitation signal to generate a second mixed signal.

According to an example embodiment of the present invention, a device for performing a method for detecting a first and a second parameter of a fluid with a sensor apparatus including an oscillator includes: means for exciting the oscillator by an excitation signal of a primary oscillator; means for exciting the oscillator via two parameters while the oscillator is in contact with the fluid, the first parameter of the fluid damping the excited oscillator via a first phase delay, and the second parameter damping the excited oscillator via a second phase delay; means for detecting an oscillation signal of the excited and damped oscillator; means for generating a first phase-shifted signal via a third phase delay from the excitation signal, the third phase delay equal to one of (a) the first phase delay and (b) the second phase delay; means for mixing the oscillation signal with the first phase-shifted signal to generate a first mixed signal; and means for averaging over time the first mixed signal to determine one of (a) the first parameter and (b) the second parameter of the fluid according to the third phase delay.

Exemplary embodiments of the present invention are explained in more detail below with reference to the appended Figures.

### BRIEF DESCRIPTION OF THE DRAWINGS

FIG. 1 is a schematic block diagram of a device according to an example embodiment of the present invention.

FIG. 2 is a schematic block diagram of a device according to an example embodiment of the present invention.

### DETAILED DESCRIPTION

In the Figures, the same reference numerals designate the same or similar components.

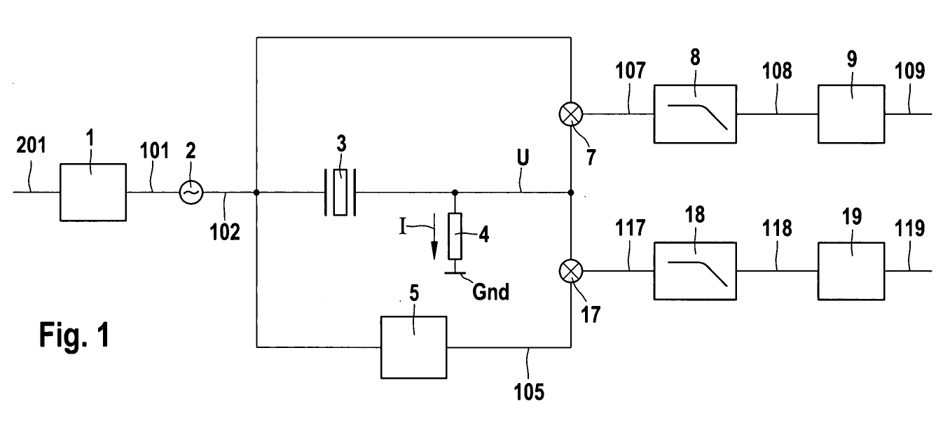

FIG. 1 is a schematic block diagram of a device of an example embodiment of the present invention. An oscillating circuit 3 is supplied with an excitation signal 102 from a primary oscillation apparatus 2. The excitation signal may be described by sin (wt), where w is the frequency of excitation signal 100 and t is the time. Oscillating circuit 3 is series-connected to a sensor resistor 4, the latter being connected to a ground Gnd. A voltage signal U, which is proportional to current flow I through sensor resistor 4 and oscillating circuit 3, is tapped at a node in oscillating circuit 3 to the sensor resistor. Voltage signal U is hereinafter referred to as the oscillation signal, since it is a measure of the amplitude of the oscillation in oscillating circuit 3. Oscillating circuit 3 includes a quartz. In a similar circuit diagram, the quartz is described by a static capacitance C₀ and a series circuit, parallel-connected thereto, including an inductance L, a capacitance C and a resistance R.

Resistance R describes the active power of the oscillating circuit and includes both ohmic loss and the mechanical work performed by the oscillating circuit in a fluid. An addend of resistance R is proportional to \sqrt{ηρ}, where η represents the dynamic viscosity and ρ the density of the viscous fluid. The resistance of oscillating circuit 3 thus rises as the viscosity increases, and current flow I through oscillating circuit 3 decreases accordingly, thereby reducing oscillation signal U. Resistance R does not change the phase of current flow I through oscillating circuit 3. Oscillation signal U, which is assigned to the viscosity, is therefore in phase with excitation signal 102.

Two terminal contacts of oscillating circuit 3 form two capacitor areas, the fluid to be analyzed also influencing the capacitance as a dielectric between the capacitors. This static capacitance C₀, which is usually regarded as parasitic, is measured and the permittivity of the dielectric fluid is thereby determined under the assumption that the terminal contacts remain constant. Static capacitance C₀ influences the phase of current I flowing through oscillating circuit 3. A purely capacitive load through oscillating circuit 3 results in a 90° phase delay between excitation signal 102 and the oscillation signal.

Total oscillation signal U thus includes one component which is in phase with excitation signal 102 and a second component which is 90° out of phase with excitation signal 102. Oscillation signal U may be divided into the two components, which correspond to the viscosity and permittivity, respectively. Excitation signal 102 and oscillation signal U are supplied to a first mixer 7 and subsequently filtered via a low-pass filter 8. Resulting signal 108 thus includes only components of oscillation signal 102 which are in phase with excitation signal 102, and it is therefore a measure of the viscosity of the fluid. In a second branch, excitation signal 102 passes through a delay unit 5 to generate a phase-shifted signal which is supplied to a second mixer together with oscillation signal U. This second mixed signal 117 is supplied to a low pass 18. Resulting signal 118 includes only the components of oscillation signal U which are 90° out of phase with excitation signal 102, making it a measure of the permittivity of the fluid. Filters 107, 117 include a filter characteristic having a time constant which is greater than a period of excitation signal U, thereby obtaining a time average for the oscillation.

The frequency of an excitation signal corresponds to a resonant frequency of oscillating circuit 3. This may provide that inductive component L and capacitance C, which specify the resonant frequency, do not contribute to the impedance of the oscillating circuit. The detection of oscillation signal U may also be regarded as a determination of the impedance of the oscillating circuit in the voltage divider formed from the oscillating circuit and sensor resistor 4. In this regard, it may be advantageous if only the viscosity and permittivity contribute to the impedance, and inductive component L and capacitance C may be minimized to obtain a high signal-to-noise ratio.

The frequency of excitation signal 102 may be periodically modulated by a central frequency, the resonant frequency of oscillating circuit 3 arranged within the modulation range. For this purpose, a control unit 1, e.g., a saw-tooth voltage generator, is connected to primary oscillation source 2. Peak value detectors 9, 19, which are connected downstream from low-pass filters 8, 118, detect the maximum values of first and second mixed signals 107 and 117, which occur upon resonant excitation of oscillating circuit 3.

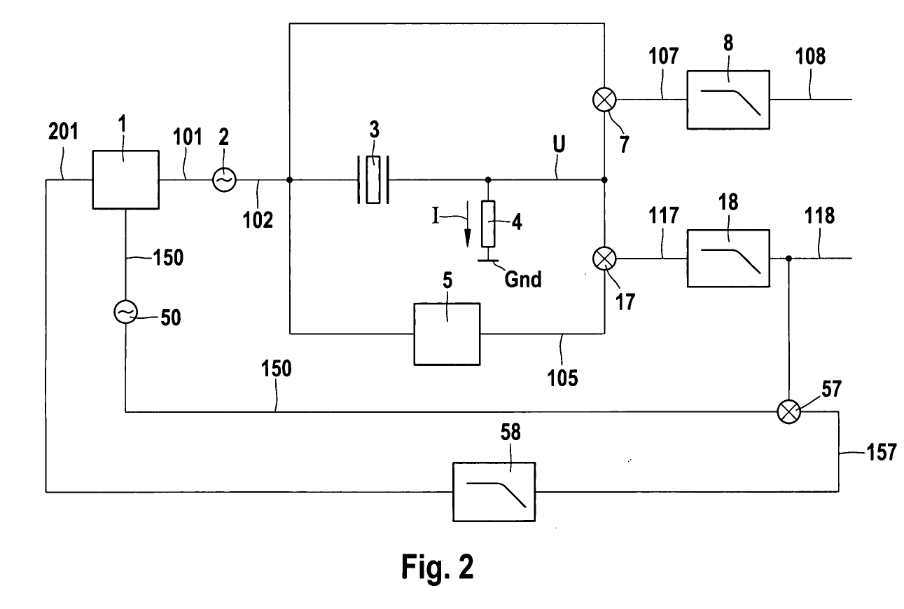

FIG. 2 is a schematic block diagram of an example embodiment of the present invention. A periodically oscillating modulation signal 150 of a modulator 50 is supplied to control unit 1 and converted by control unit 1 to a control signal 101 which is used to symmetrically frequency-modulate excitation signal 102 by a central frequency in a phase-locked manner to modulation signal 150. The frequency modulation of excitation signal 102 is transferred to the filtered, mixed first and second signals 108 and 118. As illustrated in FIG. 2, the oscillating second signal, for example, is tapped and supplied to a mixer 57 together with modulation signal 150. Mixed signal 157 is filtered by a low-pass apparatus 58 and supplied to control unit 12 in the form of a regulating signal 201. Regulating signal 201 has a first sign if the central frequency is less than the resonant frequency of oscillating circuit 3 and a second sign, which is negated in relation to the first sign, if the central frequency is greater than the resonant frequency of oscillating circuit 3. Control unit 1 sets the central frequency as a function of regulating signal 201. This achieves a closed negative feedback loop which tunes the frequency of excitation signal 102 in resonance with oscillating circuit 3. Additional components of the feedback loop may include an amplifier, integrator and/or inverter.

It should be understood that example embodiments of the present invention are not limited to combined viscosity-permittivity sensors, but may be applied to all sensors which are measurable as two signals of an oscillating circuit which are phase-shifted by 90°.

Furthermore, example embodiment of the present invention are not limited to an electrical oscillating circuit as the excited oscillator, but rather mechanically or optically excited oscillators may also be used to detect the parameters of a fluid.

### LIST OF REFERENCE CHARACTERS

1 Control unit
2 Primary oscillator
3 Oscillating circuit
4 Sensor resistor
5 Delay unit
7, 17 Mixer apparatus
8, 18 Filter apparatus
50 Modulator
57 Mixer
58 Low-pass apparatus
102 Excitation signal
105 Phase-shifted signal
107, 117 Mixed signal
150 Modulation signal
201 Regulating signal
I Current
U Oscillation signal
Gnd Ground

What is claimed is:

1. A method for detecting a first and a second parameter of a fluid with a sensor apparatus including an oscillator, comprising:
exciting the oscillator by an excitation signal of a primary oscillator;
exciting the oscillator via two parameters while the oscillator is in contact with the fluid, the first parameter of the fluid damping the excited oscillator via a first phase delay, and the second parameter damping the excited oscillator via a second phase delay;
detecting an oscillation signal of the excited and damped oscillator;
generating a first phase-shifted signal via a third phase delay from the excitation signal, the third phase delay equal to one of (a) the first phase delay and (b) the second phase delay;
mixing the oscillation signal with the first phase-shifted signal to generate a first mixed signal; and
averaging over time the first mixed signal to determine one of (a) the first parameter and (b) the second parameter of the fluid according to the third phase delay.

2. The method according to claim 1, further comprising, one of (a) sequentially and (b) in parallel to the detection, mixing and averaging over time of the first signals:
generating a second phase-shifted signal via a fourth phase delay from the excitation signal, the fourth phase delay being the second phase delay from one of (a) the first phase delay and (b) the second phase delay which was not selected;
mixing the oscillation signal with the second phase-shifted signal to generate a second mixed signal; and
averaging over time the second mixed signal to determine the other parameter of the fluid according to the fourth phase delay.

3. The method according to claim 1, wherein the oscillator includes an oscillation circuit, a current, which flows from a ground to the oscillation circuit via a sensor resistor, determined for detecting the oscillation signal of the excited oscillating circuit.

4. The method according to claim 1, wherein at least one of (a) a third phase-shifted signal is generated so that it is phase-shifted 90° in relation to the excitation signal and (b) a fourth phase-shifted signal is generated so that it is phase-shifted 0° in relation thereto.

5. The method according to claim 2, further comprising:
modulating the excitation signal by a central frequency;
obtaining a control signal by mixing one of (a) the first mixed signal and (b) the second mixed signal with the modulation signal; and
supplying the control signal to the primary oscillator apparatus to regulate the central frequency in resonance with a resonant frequency of the oscillator

6. The method according to claim 1, wherein the oscillator is excited in the exciting step in a resonant manner.

7. A device, comprising:
an oscillator connected to a primary oscillator to transmit an excitation signal of the primary oscillator to the oscillator;
a detection apparatus connected to sensor apparatus to detect an oscillation signal of an oscillating circuit;
a first delay unit arranged between a mixer apparatus and the primary oscillator to generate a third phase-shifted signal and supply the third phase-shifted signal to the mixer apparatus, which is connected to the sensor apparatus and is adapted to transmit first mixed signal to a first filter apparatus to average the first mixed signal over time.

8. The device according to claim 7, wherein the device is adapted to perform a method for detecting a first and a second parameter of a fluid with the sensor apparatus, the method including:
exciting the oscillator by the excitation signal of the primary oscillator;
exciting the oscillator via two parameters while the oscillator is in contact with the fluid, the first parameter of the fluid damping the excited oscillator via a first phase delay, and the second parameter damping the excited oscillator via a second phase delay;
detecting the oscillation signal of the excited and damped oscillator;
generating the first phase-shifted signal via a third phase delay from the excitation signal, the third phase delay equal to one of (a) the first phase delay and (b) the second phase delay;
mixing the oscillation signal with the first phase-shifted signal to generate the first mixed signal; and
averaging over time the first mixed signal to determine one of (a) the first parameter and (b) the second parameter of the fluid according to the third phase delay.

9. The device according to claim 7, wherein the oscillator includes a quartz.

10. The device according to claim 7, wherein the first delay unit includes a device having a settable phase delay.

11. The device according to claim 7, further comprising a second mixer apparatus connected to the detection apparatus and the primary oscillator to mix the oscillation signal with the excitation signal to generate a second mixed signal.

12. A device for performing a method for detecting a first and a second parameter of a fluid with a sensor apparatus including an oscillator, comprising:
means for exciting the oscillator by an excitation signal of a primary oscillator;
means for exciting the oscillator via two parameters while the oscillator is in contact with the fluid, the first parameter of the fluid damping the excited oscillator via a first phase delay, and the second parameter damping the excited oscillator via a second phase delay;
means for detecting an oscillation signal of the excited and damped oscillator;
means for generating a first phase-shifted signal via a third phase delay from the excitation signal, the third phase delay equal to one of (a) the first phase delay and (b) the second phase delay;
means for mixing the oscillation signal with the first phase-shifted signal to generate a first mixed signal; and
means for averaging over time the first mixed signal to determine one of (a) the first parameter and (b) the second parameter of the fluid according to the third phase delay.
